(19) United States
(12) Patent Application Publication
(10) Pub. No.: US 2006/0157270 A1
(43) Pub. Date: Jul. 20, 2006

(54) Printed wiring substrate and method for identifying printed wiring substrate

(75) Inventor: Yukihiro Ueno, Hiroshima (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/329,070

(22) Filed: Jan. 11, 2006

(30) Foreign Application Priority Data
Jan. 20, 2005 (JP) 2005-013023

(51) Int. Cl. H05K 1/00

(52) U.S. Cl. 174/250

(57) ABSTRACT

A printed wiring substrate has a circuit wiring area that has a circuit wiring pattern formed thereon and a peripheral area that is placed in the periphery of the circuit wiring area. The peripheral area has a property display area that is provided with a display location specified in association with a property for displaying a property of the printed wiring substrate. The property can be something that indicates an attribute of the printed wiring substrate such as production lot information, information on an inspection result of an electrical property (such as short-circuit defect, disconnection defect and wiring resistance defect), information on a visual inspection result (such as plating defect and silk screen defect), and the like.

### BACKGROUND OF THE INVENTION

This application claims priority under 35 U.S.C. § 119(a) on Patent Application No. 2005-13023 filed in Japan on Jan. 20, 2005, the entire contents of which are hereby incorporated by reference.

The present invention relates to a printed wiring substrate that is applied to an electronic device and the like and whose property (such as production lot information and inspection result information) can be identified, and further relates to a method for identifying a printed wiring substrate that identifies such a printed wiring substrate.

Conventionally, in a process for manufacturing (process for mass production) printed wiring substrates, a production lot number, a history of pattern change, and the like are generally displayed using screen printing and the like so that a character pattern or symbol pattern is displayed or using a conductor pattern that has been formed simultaneously with a circuit wiring pattern so that a history symbol is displayed.

In addition, as a method for displaying a defect when a circuit wiring pattern is inspected for disconnection or short-circuit using a bare board tester or the like in a process for manufacturing, a method in which a mark is added in ink near the location where a defect has occurred has been known (for example, see JP S61-278738).

In addition, for a defect, such as print offset, inclusion and irregular color, that is discovered through an appearance inspection in a process for manufacturing, a visual inspection or a simple optical inspection device has often been used as a process for such an inspection, and a method in which a label or the like that indicates the description of a defect is attached thereon has often been performed.

In order to display a production lot number and a history of pattern change using a character pattern or a symbol pattern, a printing plate, an exposure film, and the like need to be re-prepared and much cost, time, and labor are necessary. To limit this cost, in displaying a production lot number and the like, a method in which many small-sized circles are arranged in advance and circles are eliminated one by one at every lot change has also been used. In other words, in terms of task, small-sized circles on a printing plate are filled one by one.

With this method, although it is possible to display a production lot number or a history of pattern change, the only possible identification is through visual confirmation, and still more, it is difficult to distinguish at a glance if the number of the small circles is smaller or larger by one. Therefore, it has been difficult to identify, for example, a product from one with a different lot that became mixed in when a lot was changed or when similar printed wiring substrates are produced at the same time.

Furthermore, conventional methods that have been adopted include a method in which a label is prepared according to the description of a defect and attached to the printed wiring substrate and a method in which the location of a defect is recorded in the computer of the inspection device based on the ID that has been assigned to each printed wiring substrate so that the description of the defect can be identified by setting the corresponding printed wiring substrate on a dedicated verifying station.

However, there are problems in that a method using IDs complicates a process for processing and in that a method using labels entails risks including displacement and transfer of labels.

In addition, in performing an inspection of printed wiring substrates as products, it is important to prevent defectives from mixing in to regular products (conforming products). With the conventional methods in which a mark is formed in ink or an identification label is attached near the location of a defect, it is difficult to detect and identify a defective printed wiring substrates in case of mixing in of a defective.

Furthermore, it is impossible to distinguish the quantity and type of the existing defects when many printed wiring substrates are stacked with one another in a process for mass production or the like. In addition, even when they are stacked after being classified by the type of defect, in case of mixing in of a part with a different type of defect, it cannot be identified unless the substrates are confirmed one by one.

Moreover, in a product inspection, although it is necessary to quickly summarize the description of the defects of the products that are determined to be defective so that the causes of the defects can be identified and a quick feedback can be given to the process, the methods that involve label attachment or marking in ink require visual identification or the like of each one of the printed wiring substrates, and in this case only manual classification and counting (summarization) are possible.

In addition, although it is not impossible to perform classification (identification) with image processing or an electromagnetic method, circumstances do not allow easy utilization thereof since expensive and complex equipment is necessary.

### SUMMARY OF THE INVENTION

The present invention is carried out in view of the above-described problems, and has an object of providing a printed wiring substrate that, by providing a property display area that is provided with a display location specified in association with a property of a printed wiring substrate in a peripheral area or in a protrusion portion that protrudes outside of the peripheral area, makes it possible to form an identifying means at a display location that is associated with a property of the printed wiring substrate.

In addition, the present invention has another object of providing a method for identifying a printed wiring substrate that makes it possible to easily identify a property of a printed wiring substrate by forming an identifying means at a display location that is associated with a property of a printed wiring substrate, the printed wiring substrate in which a property display area is provided with the display location for displaying a property of a printed wiring substrate is formed in a peripheral area or in a protrusion portion that protrudes outside of a peripheral area.

A printed wiring substrate according to the present invention is a printed wiring substrate having a circuit wiring area that has a circuit wiring pattern formed thereon and a peripheral area that is placed in the periphery of the circuit wiring area, wherein a property display area that is provided with a display location specified in association with a property for displaying a property of the printed wiring substrate is placed in the peripheral area.

This configuration makes it possible to form an identifying means at a display location in association with a property of the printed wiring substrate, whereby the printed wiring substrate can be easily identified.

In addition, a printed wiring substrate according to the present invention may be a printed wiring substrate having a circuit wiring area that has a circuit wiring pattern formed thereon and a peripheral area that is placed in the periphery of the circuit wiring area having, instead of the above-described configuration, a configuration in which a property display area that is provided with a display location specified in association with a property for displaying a property of the printed wiring substrate is provided on a protrusion portion that is formed so as to protrude outside of the periphery area.

This configuration makes it possible to freely set the size and the location of the property display area even when the property display area cannot be provided on the periphery area.

In addition, in the printed wiring substrate according to the present invention, the peripheral area may be a waste plate area that is to be cut and discarded prior to incorporation of the printed wiring substrate into a product. This configuration makes it possible to effectively utilize the waste plate area.

In addition, in the printed wiring substrate according to the present invention, a means for displaying location to indicate the display location may be formed in the property display area. This configuration in which the display location can be directly (visually) recognized, and an identifying means can be reliably and easily formed and identified, makes it possible to improve the processing accuracy and the processing speed.

In addition, in the printed wiring substrate according to the present invention, a property description display portion that shows a description of a property in association with the means for displaying location may be formed. This configuration, in which a description of a property associated with a means for displaying location can be visually confirmed, makes it possible to improve convenience, processing accuracy and processing speed in a process for processing.

In addition, in the printed wiring substrate according to the present invention, the means for displaying location may be a lingulate segment. This configuration makes it possible to reliably display location and easily form an identifying means.

In addition, in the printed wiring substrate according to the present invention, the means for displaying location may be a location display pattern. This configuration makes it possible to easily form a means for displaying location.

In addition, in the printed wiring substrate according to the present invention, the location display pattern may simultaneously serve as the property description display portion. This configuration makes it possible to visually confirm a display location and a description of a property in a reliable manner, and to reduce the planar dimension occupied by the property display area, whereby the size of the printed wiring substrate can be reduced.

In addition, in the printed wiring substrate according to the present invention, the location display pattern may be a conductor pattern formed in the same process as the circuit wiring pattern. This configuration makes it possible to easily form the location display pattern, clearly display the location display pattern, and detect an identifying means using an electrical detecting means.

In addition, in the printed wiring substrate according to the present invention, the property may be production lot information. This configuration, in which a lot can be easily and reliably identified when a plurality of production lots are processed, makes it possible to reliably prevent lot mixing.

In addition, in the printed wiring substrate according to the present invention, the property may be inspection result information. This configuration, in which the mode of an inspection failure can be accurately and quickly understood, makes it possible to improve operation efficiency in a process for processing.

In addition, to achieve the above-described objects, a method for identifying a printed wiring substrate according to the present invention is a method for identifying a printed wiring substrate having a circuit wiring area that has a circuit wiring pattern formed thereon and a peripheral area that is placed in the periphery of the circuit wiring area, in which a property display area that is provided with a display location specified in association with a property for displaying a property of the printed wiring substrate is placed in the peripheral area, and an identifying means is formed in the display location that is associated with a property of the printed wiring substrate.

This configuration makes it possible to easily and reliably identify for example, production lot information and inspection result information as a property of a printed wiring substrate by detecting an identifying means that is formed on a corresponding display location.

In addition, the method for identifying a printed wiring substrate according to the present invention may be, instead of the above-described configuration, a method for identifying a printed wiring substrate having a circuit wiring area that has a circuit wiring pattern formed thereon and a peripheral area that is placed in the periphery of the circuit wiring area, in which a property display area that is provided with a display location specified in association with a property for displaying a property of the printed wiring substrate is placed on a protruding portion formed so as to protrude outside of the peripheral area, and an identifying means is formed in the display location that is associated with a property of the printed wiring substrate.

This configuration makes it possible to identify a printed wiring substrate by detecting a formed identifying means since an identifying means can be formed even when the property display cannot be formed on the periphery area.

In addition, in the method for identifying a printed wiring substrate according to the present invention, a property description display portion for displaying a description of a property may be formed in association with the display location. This configuration makes it possible to visually confirm the description of a property in an easy and direct manner, whereby convenience, processing accuracy, and processing speed in a process for processing can be improved.

In addition, in the method for identifying a printed wiring substrate according to the present invention, the identifying means may be an opening portion. This configuration makes it possible to easily form an identifying means with a simple jig, and to visually confirm the identifying means in a reliable manner.

In addition, in the method for identifying a printed wiring substrate according to the present invention, the opening portion may be formed by removing a lingulate segment that has been formed in association with the display location. This configuration, in which influences on the printed wiring substrate, jig, equipment, and the like can be eliminated since the lingulate segment can be easily broken off, makes it possible to achieve a stable and simple identifying method.

In addition, in the method for identifying a printed wiring substrate according to the present invention, the opening portion may be formed by removing a conductor pattern that has been formed in association with the display location. This configuration, in which a display location that is in association with a property can be detected using an electrical detecting means, makes it possible to identify a printed wiring substrate in an easy and reliable manner.

In addition, in the method for identifying a printed wiring substrate according to the present invention, the identifying means may be a mark. In this configuration, an identifying means can be easily formed, and an identifying means can be visually confirmed in a reliable manner.

In addition, in the method for identifying a printed wiring substrate according to the present invention, the mark may be formed in association with a location display pattern that indicates the display location. This configuration makes it possible to visually confirm the display location that is associated with the mark in an easy manner.

In addition, in the method for identifying a printed wiring substrate according to the present invention, the location display pattern may also serve as the property description display portion. This configuration makes it possible to visually confirm a display location as well as a description of a property in a reliable manner, and to reduce the planar dimension occupied by the property display area, whereby the size of the printed wiring substrate can be reduced.

In addition, in the method for identifying a printed wiring substrate according to the present invention, the mark may be formed by applying an insulating material to a conductor pattern that has been formed as the location display pattern. This configuration, in which the mark can be easily formed and the display location associated with a property can be detected using an electrical detecting means, makes it possible to identify a printed wiring substrate in an easy and reliable manner.

In addition, in the method for identifying a printed wiring substrate according to the present invention, the mark may be formed on the side edge surface of the property display area. This configuration makes it possible to easily identify a printed wiring substrate even when a plurality of printed wiring substrates are stacked with one another by simply aligning the side end surface.

In addition, in the method for identifying a printed wiring substrate according to the present invention, the property may be production lot information. This configuration makes it possible to reliably prevent lot mixing-in when a plurality of production lots are processed.

In addition, in the method for identifying a printed wiring substrate according to the present invention, the property may be inspection result information. This configuration makes it possible to reliably and quickly understand the mode of an inspection failure.

In addition, in the method for identifying a printed wiring substrate according to the present invention, the property identified with an identifying means may be detected using a detecting means. Moreover, the detecting means is preferably either optical, mechanical, or electrical. Furthermore, the result of detection by the detecting means may be summarized. These configurations make it possible to easily detect an identifying means using a detecting means, and efficiently summarize the result of identification and detection of a printed wiring substrate.

In addition, in the method for identifying a printed wiring substrate according to the present invention, the protruding portion may be removed prior to shipment of the printed wiring substrate. This configuration makes it possible to prevent leakage of information such as inspection conditions in a process for processing.

### BRIEF DESCRIPTION OF THE DRAWINGS

FIG. 1 is a plan view that shows the outline of the plane surface of a printed wiring substrate according to Embodiment 1 of the present invention.

FIG. 2 is a plan view that shows the outline of the plane surface of a printed wiring substrate according to Embodiment 2 of the present invention.

FIG. 3 is a plan view that shows the outline of the plane surface of a printed wiring substrate according to Embodiment 3 of the present invention.

FIG. 4 is a plan view that shows the outline of the relevant portion of the plane surface of a printed wiring substrate according to Embodiment 4 of the present invention.

FIG. 5 is a plan view that shows the outline of the relevant portion of the plane surface of a printed wiring substrate according to Embodiment 5 of the present invention.

FIG. 6 is a plan view that shows the outline of the relevant portion of the plane surface of a printed wiring substrate according to Embodiment 6 of the present invention.

FIG. 7 is a plan view that shows the outline of the relevant portion of the plane surface of a printed wiring substrate for explaining a method for identifying a printed wiring substrate according to Embodiment 7.

FIG. 8 is a plan view that shows the outline of the relevant portion of the plane surface of a printed wiring substrate for explaining a method for identifying a printed wiring substrate according to Embodiment 8.

FIG. 9 is a plan view that shows the outline of the relevant portion of the plane surface of a printed wiring substrate for explaining a method for identifying a printed wiring substrate according to Embodiment 9.

FIG. 10 is a plan view that shows the outline of the relevant portion of the plane surface of a printed wiring substrate for explaining a method for identifying a printed wiring substrate according to Embodiment 10.

FIG. 11 is a plan view that shows the outline of the relevant portion of the plane surface of a printed wiring substrate for explaining a method for identifying a printed wiring substrate according to Embodiment 11.

FIG. 12 is a perspective view that shows the outline of the relevant portions of the plane surface and side edge surface of a printed wiring substrate for explaining a method for identifying a printed wiring substrate according to Embodiment 12.

FIG. 13 is a perspective view that shows the outline of the relevant portion of the side edge surface in a state in which a plurality of printed wiring substrates are stacked for explaining a method for identifying a printed wiring substrate according to Embodiment 13.

FIG. 14 is a plan view that shows the outline of the relevant portion of the plane surface of a printed wiring substrate for explaining a method for identifying a printed wiring substrate according to Embodiment 14.

FIG. 15 is a plan view that shows the outline of the relevant portion of the plane surface of a printed wiring substrate for explaining a method for identifying a printed wiring substrate according to Embodiment 15.

FIG. 16 is a perspective view that explains a method for identifying a printed wiring substrate according to Embodiment 16 of the present invention.

FIG. 17 is a perspective view that explains a method for identifying a printed wiring substrate according to Embodiment 17 of the present invention.

### DESCRIPTION OF THE PREFERRED EMBODIMENTS

Hereinafter, embodiments of the present invention win be described with reference to the accompanying drawings.

### <Embodiment 1>

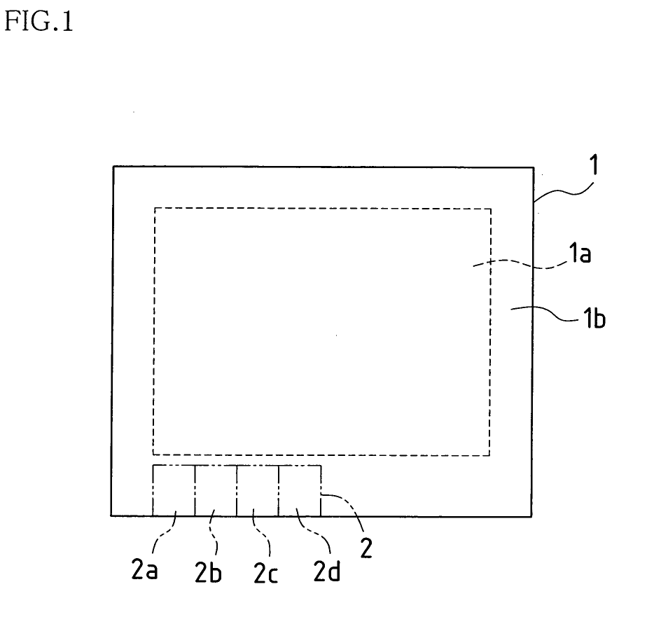

FIG. 1 is a plan view that shows the outline of the plane surface of a printed wiring substrate according to Embodiment 1 of the present invention.

A printed wiring substrate 1 has been formed in an outside dimension that can be incorporated into a product as is. The printed wiring substrate 1 has a circuit wiring area 1a that has a circuit wiring pattern formed thereon and a peripheral area 1b that is placed in the periphery of the circuit wiring area.

The peripheral area 1b is the peripheral portion of the printed wiring substrate 1 that is to be incorporated into a product (portion as an allowance for handling of the printed wiring substrate 1, such as fixing and shipping, in a process for mounting components and the like, portion as a reinforcement for the protection of the periphery of the circuit wiring area 1a, and portion as a structure necessary for incorporation into a product).

The peripheral area 1b is provided with a property display area 2 that is provided with display locations 2a, 2b, 2c, and 2d specified in association with a property so that the property of the printed wiring substrate 1 is displayed. The property can be something that shows an attribute of the printed wiring substrate 1 such as production lot information (production lot number), information on an inspection result of an electrical property (such as short-circuit defect, disconnection defect and wiring resistance defect) and information on a visual inspection result (such as plating defect and silk screen defect). Accordingly, for example, “lots A, B, C, and D” can be associated with the “display locations 2a, 2b, 2c, and 2d” respectively. It is needless to say that the display locations (2a, 2b, 2c, and 2d) are not limited to four.

The display locations 2a, 2b, 2c, and 2d are acceptable if their respective locations are specified within the property display area 2. In addition, although it is acceptable to use a line segment (double dot-dashed line in the drawing) or the like as a means for displaying location of the display locations 2a, 2b, 2c, and 2d so that they are sectionalized, it is not always necessary to provide a visible display. This is because an auxiliary scale or the like can be placed externally to substitute the means for displaying location. The segment line (double dot-dashed line in the drawing) can be formed by printing or at the same time as formation of a circuit wiring pattern that is formed on the circuit wiring area 1a.

According to the printed wiring substrate 1 according to this embodiment, (a property of) the printed wiring substrate 1 can be easily identified by forming an identifying means (see an opening portion 10) in association with a property, as described in Embodiment 7 below, etc. For example, by specifying that the production lot number A of the printed wiring substrate 1 be associated with the display location 2a, the production lot number A of the printed wiring substrate 1 can be identified through formation of an appropriate identifying means at the display location 2a within the property display area 2. In addition, this application is not limited to a production lot number, and can also be used when a plurality of similar products are manufactured, when specifications differ depending on the product destination, when single printed wiring substrates 1 (with the same circuit wiring pattern) in different grades are shipped, when designs are changed, or the like.

According to this embodiment, since the property display area that is provided with the display locations associated with properties is provided, and an identifying means can be formed at a display location (predetermined fixed location) associated with a property of the printed wiring substrate, the quantity of or mixing in of printed wiring substrates with different properties, as well as a description of a property can be visually identified, summarized, etc. at a glance.

### <Embodiment 2>

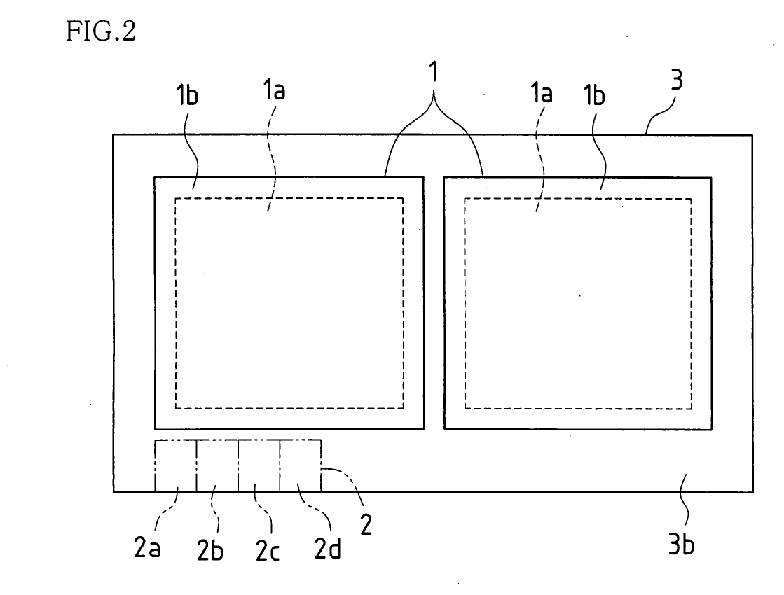

FIG. 2 is a plan view that shows the outline of the plane surface of a printed wiring substrate according to Embodiment 2 of the present invention. The same numeric references will be used for the same configuration as Embodiment 1 and detailed explanation will be omitted when deemed appropriate.

A printed wiring substrate 3 includes a plurality of the printed wiring substrates 1 according to Embodiment 1 (two in this example) and has a waste plate area 3b as a peripheral area that is to be cut and discarded prior to incorporation into a product, which, in general, is also called “wiring board in kit.” The waste plate area 3b that corresponds to the peripheral area 1b according to Embodiment 1 is provided with a property display area 2. Although roles of the waste plate area 3b are basically the same as that of the peripheral area 1b, an additional role of connecting the plurality of printed wiring substrates 1 is also taken in this embodiment.

### <Embodiment 3>

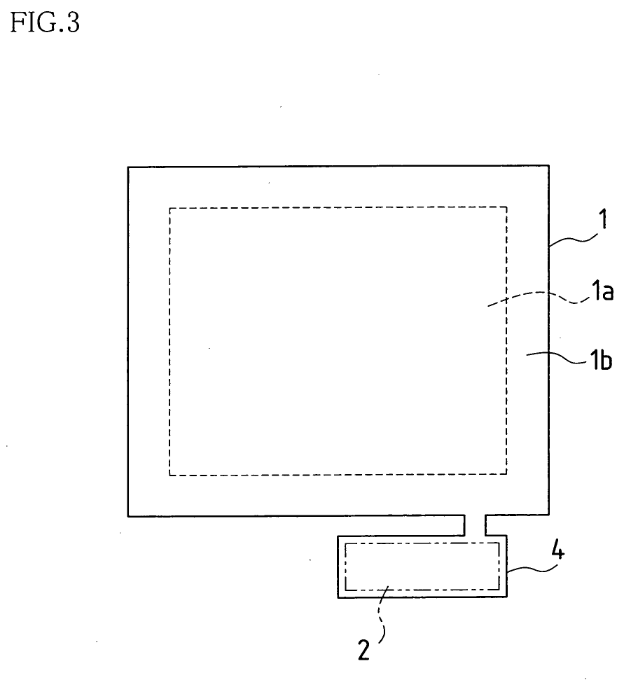

FIG. 3 is a plan view that shows the outline of the plane surface of a printed wiring substrate according to Embodiment 3 of the present invention. The same numeric references will be used for the same configuration as Embodiments 1 and 2 and detailed explanation will be omitted when deemed appropriate.

The printed wiring substrate 1 is provided with a protrusion portion 4 that is formed so as to protrude outside of the peripheral area 1b. Like Embodiments 1 and 2, the protrusion portion 4 has a property display area 2 formed thereon. It is needless to say that the property display area 2 is provided with display locations (2a, 2b, 2c, and 2d: not shown) like in Embodiments 1 and 2.

Although an example in which the protrusion portion 4 is formed outside of the printed wiring substrate 1 (peripheral area 1b) is described in this embodiment, needless to say, the protrusion portion 4 can also be formed on the outside of the printed wiring substrate 3 (waste plate area 3b) described in Embodiment 2.

Even when it is difficult to form the property display area 2 on the printed wiring substrate 1 (peripheral area 1b) or the printed wiring substrate 3 (waste plate area 3b), the same effects as Embodiments 1 and 2 can be obtained since the protrusion portion 4 that is provided with the property display area 2 is separately provided. In addition, it is needless to say that the following embodiments can be applied in a similar manner to the property display area 2 of the protrusion portion 4.

Since the protrusion portion 4 is usually unnecessary for users of the printed wiring substrate 1, it can be removed prior to shipment of the product, and leakage of the processing status to outside can be prevented by the removal. Nevertheless, utilization in concert with users is also possible, and shipment can be made with the protrusion 4 left as well. cl <Embodiment 4 >

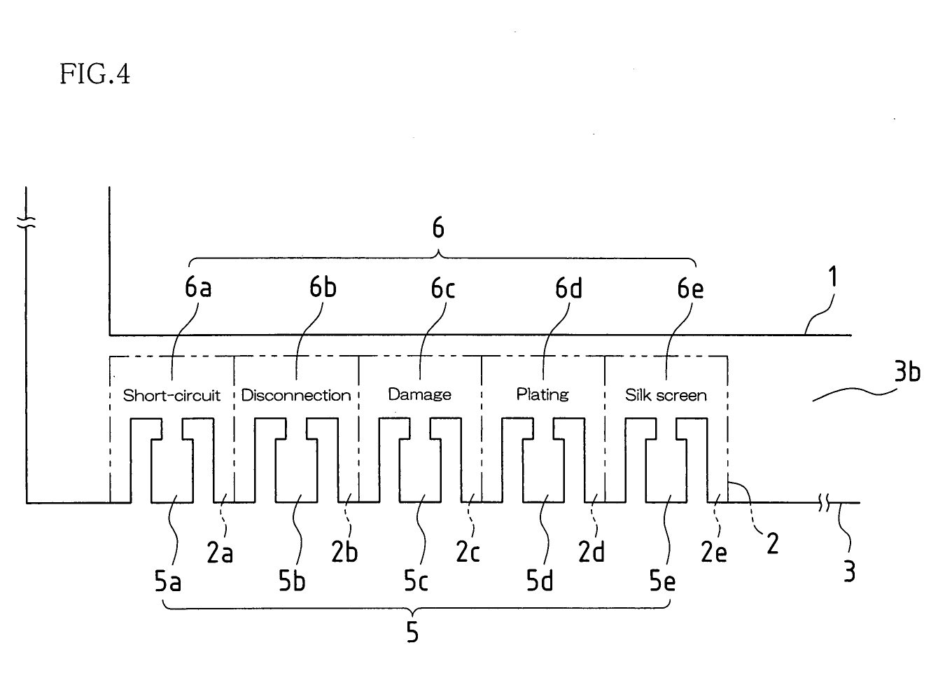

FIG. 4 is a plan view that shows the outline of the relevant portion of the plane surface of a printed wiring substrate according to Embodiment 4 of the present invention. The same numeric references will be used for the same configuration as the embodiments described above and detailed explanation will be omitted when deemed appropriate.

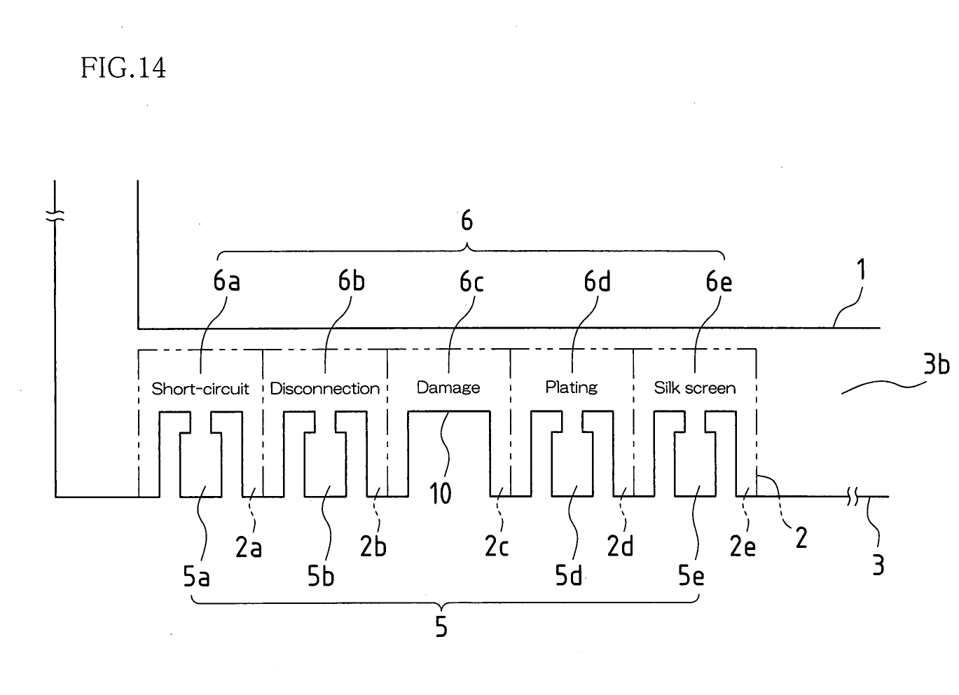

A discarding plate area 3b of a printed wiring substrate 3 that includes a printed wiring substrate 1 therein has a property display area 2 formed thereon. The property display area 2 has lingulate segments 5a, 5b, 5c, 5d, and 5e (when it is not necessary to distinguish the lingulate segments 5a, 5b, 5c, 5d, and 5e from one another, they are simply referred to as lingulates 5) formed thereon as a means for displaying location to indicate display locations 2a, 2b, 2c, 2d, and 2e. An opening portion 10 (see Embodiment 14 and FIG. 14) as an identifying means can be easily and reliably formed by removing the lingulates 5 based on the properties.

Although an example in which the property display area 2 is formed on the waste plate area 3b of the printed wiring substrate 3 is described, needless to say, the application is also possible in the same manner when the property display area 2 is formed in the peripheral area 1b of the printed wiring substrate 1.

In addition, property description display portions 6a, 6b, 6c, 6d, and 6e (when it is not necessary to distinguish the property description display portions 6a, 6b, 6c, 6d, and 6e from one another, they are simply referred to as property description display portions 6) that display a description of a property that is associated with the respective lingulate segments 5a, 5b, 5c, 5d, and 5e are formed. The property description display portions 6 are acceptable as long as they are associated with the means for displaying location (lingulate segments 5), and they can be placed either inside or outside of the property display area 2.

The property description display portions 6a, 6b, 6c, 6d, and 6e have the displays “Short-circuit,” “Disconnection,” “Damage,” “Plating,” and “Silk screen” that are associated with the properties short-circuit defect, disconnection defect, damage defect, plating defect, and silk screen defect respectively. The property description display portions 6 can be formed at the same time as formation of a circuit wiring pattern that is to be formed on a circuit wiring area la or can be printed as appropriate using another means.

The property description display portions 6 can be a description of a property in a direct manner as described in this embodiment, or can be described in an indirect manner using other expressions. It is also acceptable to use an encryption so that the conditions of a process for inspecting the printed wiring substrate 3 cannot be guessed when the printed wiring substrate 3 is exposed outside.

As described in this embodiment, the property description display portions 6 can be configured so that inspection result information is shown (in other words, the properties to be shown are inspection result information). If this configuration is selected, the printed wiring substrates 3 that have gone through the inspection can be quickly and accurately sorted based on the inspection results, which increases convenience in a process for processing.

In addition, there is a possibility in which the printed wiring substrate 3 that has not yet been inspected escapes to be shipped as is when the non-inspected printed wiring substrate 3 becomes mixed in to the inspected wiring substrates 3 in a process for inspecting the printed wiring substrate 3. For this reason, it is also acceptable to have the property description display portions 6 also display the fact that it is a conforming product in addition to when the inspection result is defective. With this configuration, it is possible to reliably identify 100% inspected products as well as to guarantee that they are 100% inspected.

The property description display portions 6 can be configured so that they show production lot information (in other words, the properties to be indicated is production lot information) by specifying the property description display portions 6 to be character patterns A, B, C, D, and E that are associated with production lot numbers A, B, C, D, and E. With this configuration, lot mixing in a process for manufacturing can be easily prevented, and convenience and accuracy in a process for processing improve.

Although the property description display portions 6 can be formed in the same process as the circuit wiring pattern, they can be easily formed using resist ink or silk screen printing as appropriate.

### <Embodiment 5 >

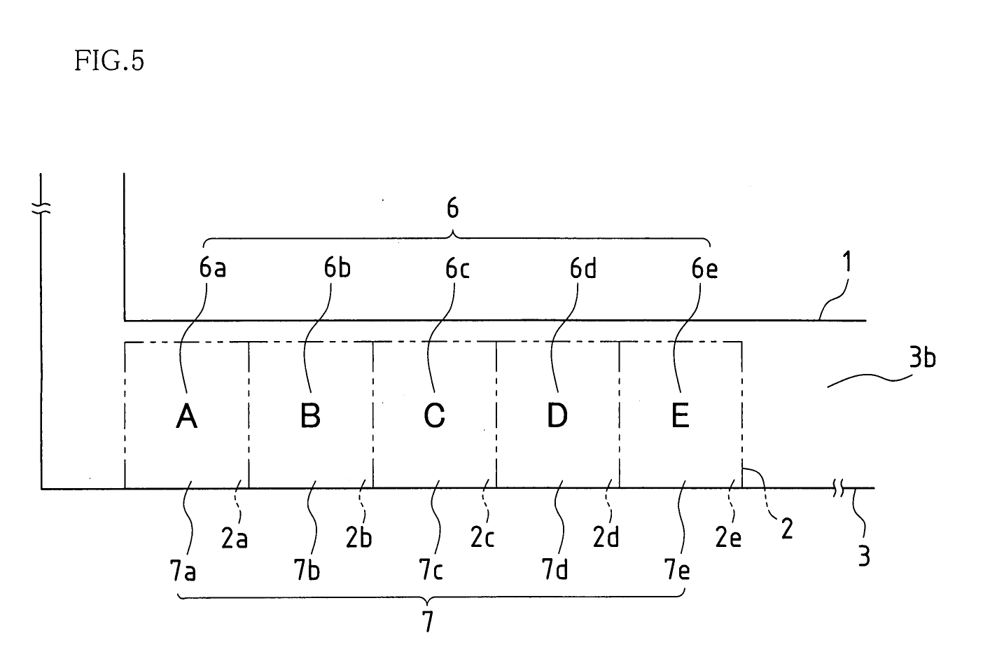

FIG. 5 is a plan view that shows the outline of the relevant portion of the plane surface of a printed wiring substrate according to Embodiment 5 of the present invention. The same numeric references will be used for the same configuration as the embodiments described above and detailed explanation will be omitted when deemed appropriate.

A property display area 2 has location display patterns 7a, 7b, 7c, 7d, and 7e (when it is not necessary to distinguish the location display patterns 7a, 7b, 7c, 7d, and 7e from one another, they are simply referred to as location display patterns 7) as a means for displaying location to indicate display locations 2a, 2b, 2c, 2d, and 2e formed thereon. In this embodiment, character patterns A to E are displayed as the location display patterns 7. The location display patterns 7 can be formed at the same time as formation of a circuit wiring pattern that is to be formed on a circuit wiring area 1a, or can be formed as appropriate using another means such as resist ink and silk screen printing. In other words, the means for displaying location can be easily formed similarly to the property description display portions 6 by specifying the location display patterns 7 as the means for displaying location.

The location display patterns 7 can concurrently serve as the property description display portions 6 when the character patterns A, B, C, D, and E are also the production lot numbers A, B, C, D, and E that are associated with the property description display portions 6. In this case, the area occupied by the property display area 2 can be reduced.

In addition, the property description display portions 6 can be configured so that production lot information is shown as described in this embodiment. In this configuration, lot mixing or the like in a process for manufacturing can be easily prevented and convenience in a process for processing improves.

For the location display patterns 7, a pattern of character, symbol, pattern, and the like can be selected as appropriate. By differentiating the display descriptions between the location display patterns 7a, 7b, 7c, 7d, and 7e, display location associated with a property can be specified with an appropriate pattern or the like, and mixing in of the printed wiring substrates 3 with different properties can be prevented.

In addition, it is needless to say that the configuration that indicates inspection result information similarly to as described in Embodiment 4 can be achieved by displaying short-circuit, disconnection, damage, plating, and silk screen instead of the character patterns A to E as the location display patterns 7.

### <Embodiment 6 >

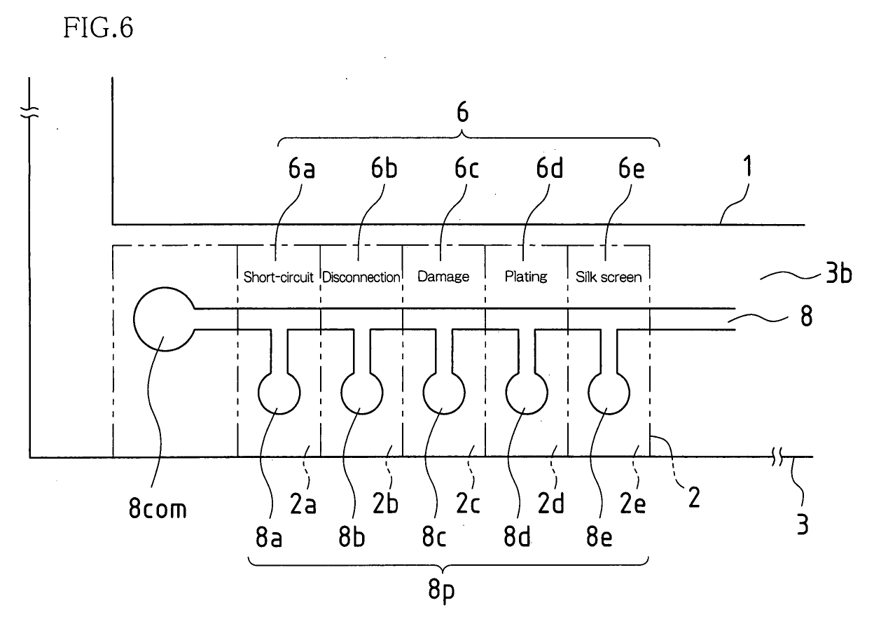

FIG. 6 is a plan view that shows the outline of the relevant portion of the plane surface of a printed wiring substrate according to Embodiment 6 of the present invention. The same numeric references will be used for the same configuration as the embodiments described above and detailed explanation will be omitted when deemed appropriate.

A property display area 2 has a conductor pattern 8 formed thereon as location display patterns (means for displaying location) that indicate display locations 2a, 2b, 2c, 2d, and 2e. The conductor pattern 8 can be formed in the same process as a circuit wiring pattern that is to be formed on the circuit wiring area 1a. The conductor pattern 8 is electrically conducted to a common pad 8com, and has conductor pads 8a, 8b, 8c, 8d, and 8e (when it is not necessary to distinguish the conductor pads 8a, 8b, 8c, 8d, 8e from one another, they are simply referred to as conductor pad 8p) that are in association with the display locations 2a, 2b, 2c, 2d, and 2e. In other words, since the conductor patterns 8 (conductor pad 8p) are in association with the display locations 2a, 2b, 2c, 2d, and 2e, they can also be made to work as the location display patterns (means for displaying location).

In addition, property description display portions 6 are formed so as to be associated with the conductor patterns 8 (conductor pad 8p). The property description display portions 6 work as described above.

### <Embodiment 7 >

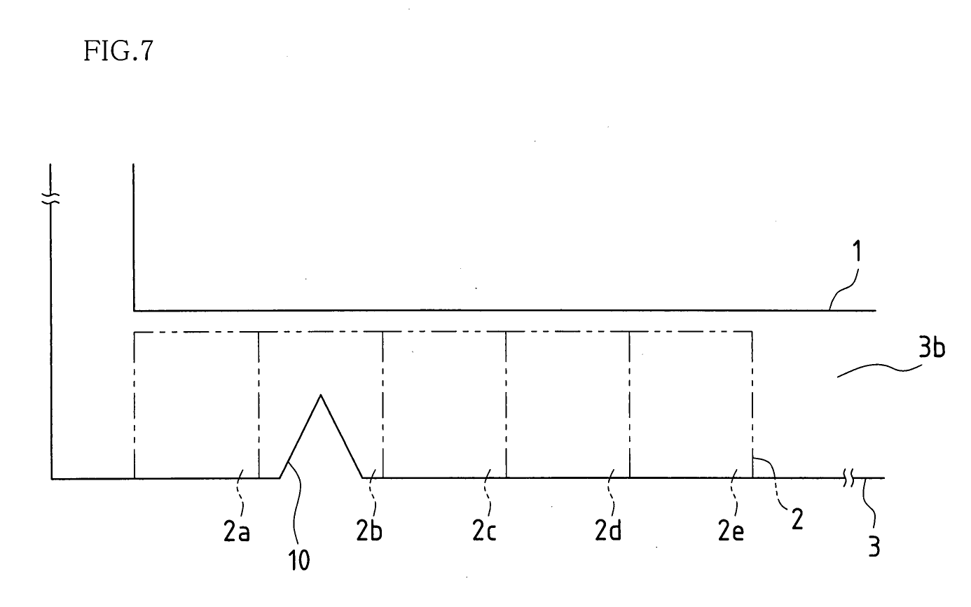

FIG. 7 is a plan view that shows the outline of the relevant portion of the plane surface of a printed wiring substrate for explaining a method for identifying a printed wiring substrate according to Embodiment 7 of the present invention. The same numeric references will be used for the same configuration as the embodiments described above and detailed explanation will be omitted when deemed appropriate.

An opening portion 10 is formed on a property display area 2 as an identifying means to identify a printed wiring substrate 3 according to properties of the printed wiring substrate 3. The opening portion 10 is formed as a notch in the shape, for example, of a triangle in a plan view in a location that corresponds to a display location 2b of the property display area 2. In other words, the printed wiring substrate 3 can be identified as having a property that corresponds to the display location 2b.

In addition, without limitation to this embodiment, properties of the printed wiring substrate 3 can be identified based on the presence or absence, corresponding display locations (2a, 2b, 2c, 2d, or 2e), quantity, and the like of the opening portion 10. In other words, by detecting the identifying means (opening portion 10) that is formed in the property display area 2, production lot information, inspection result information, and the like that serves as the property can be identified.

The opening portion 10 is not limited to a notch and can be a hole (see Embodiment 9). Formation of a notch or a hole only requires addition of a pin or the like that is suitable for the notch or hole to form to a die for processing of outer shape, and with this method, the notch or the hole can be easily formed. In addition, it is also acceptable to prepare a jig or the like as appropriate so that the notch or the hole can be formed manually or with a simple jig/equipment. Furthermore, location, shape, and quantity of the opening portion 10 can be easily changed without changing or preparing a die.

If the display locations 2a, 2b, 2c, 2d, and 2e are associated with, for example, the production lot numbers A, B, C, D, and E in this embodiment, the printed wiring substrate 3 can be identified as having the production lot number B based on the fact that the opening portion 10 is formed at the display location 2b.

### <Embodiment 8>

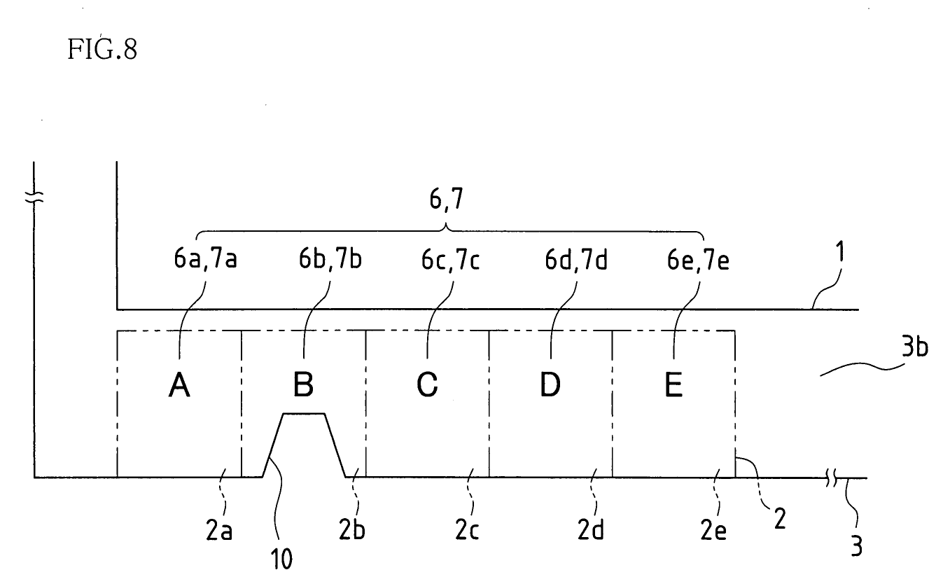

FIG. 8 is a plan view that shows the outline of the relevant portion of the plane surface of a printed wiring substrate for explaining a method for identifying a printed wiring substrate according to Embodiment 8 of the present invention. The same numeric references will be used for the same configuration as the embodiments described above and detailed explanation will be omitted when deemed appropriate.

A printed wiring substrate 3 according to this embodiment is the same as the printed wiring substrate 3 described in Embodiment 5, and has character patterns A, B, C, D, E formed thereon that serve both as property description display portions 6 (6a, 6b, 6c, 6d, and 6e) and as location display patterns 7 (7a, 7b, 7c, 7d, and 7e) as a means for displaying location.

An opening portion 10 is formed as an identifying means in the property display area 2 of the printed wiring substrate 3 that is described in Embodiment 5. The opening portion 10 is formed as a notch in the shape, for example, of a trapezoid in a plan view in a location that corresponds to the display location 2b of the property display area 2. In other words, the printed wiring substrate 3 can be identified as having a property that is associated with the character pattern B.

### <Embodiment 9>

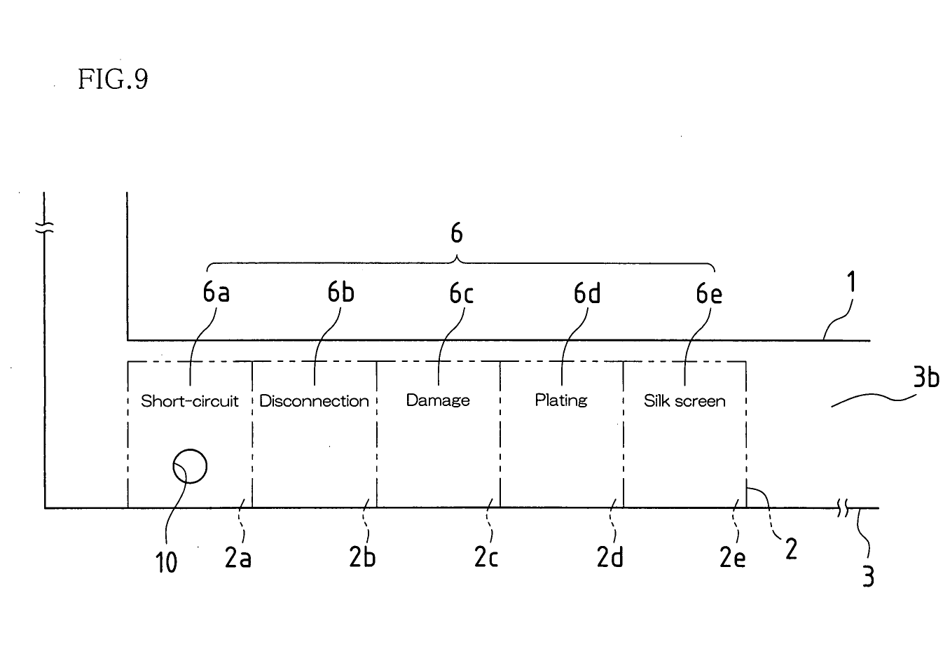

FIG. 9 is a plan view that shows the outline of the relevant portion of the plane surface of a printed wiring substrate for explaining a method for identifying a printed wiring substrate according to Embodiment 9 of the present invention. The same numeric references will be used for the same configuration as the embodiments described above and detailed explanation will be omitted when deemed appropriate.

An opening 10 as an identifying means is formed as a hole with the shape of a circle in plan view in (a display location 2a of) a property display area 2, and property description display portions 6 that show the description of a property are formed in association with display locations 2a, 2b, 2c, 2d, and 2e. The property description display portions 6 are specified to display information on inspection results such as short-circuit, disconnection, and the like. For example, the printed wiring substrate 3 can be identified as having a short-circuit defect based on the opening portion 10 formed in the display location 2a.

### <Embodiment 10>

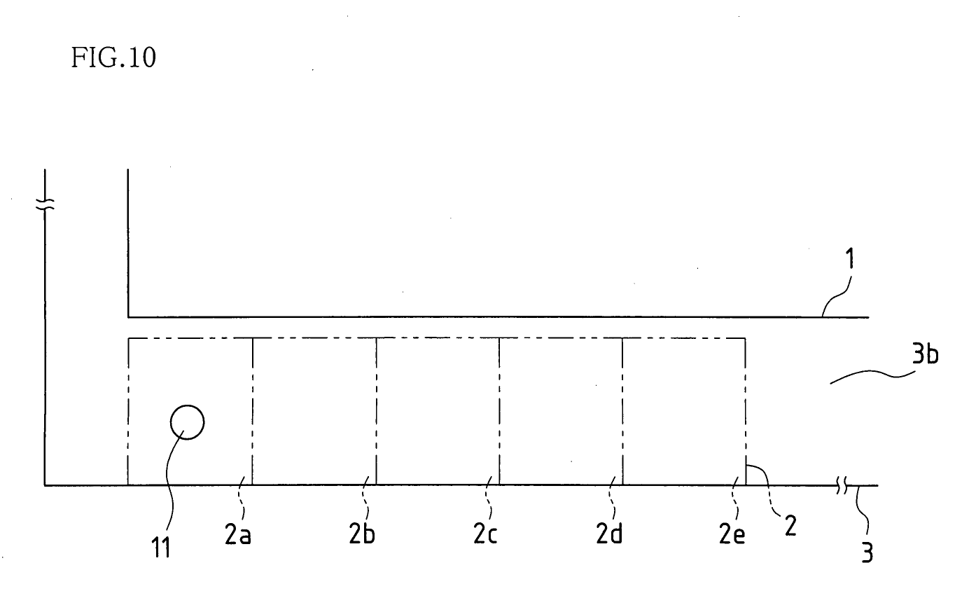

FIG. 10 is a plan view that shows the outline of the relevant portion of the plane surface of a printed wiring substrate for explaining a method for identifying a printed wiring substrate according to Embodiment 10 of the present invention. The same numeric references will be used for the same configuration as the embodiments described above and detailed explanation will be omitted when deemed appropriate.

In this embodiment, instead of the opening portion 10 for identifying a printed wiring substrate 3, a mark 11, which has the same functions as Embodiment 7, is formed as an identifying means in the property display area 2. In other words, since the mark 11 is formed, for example, on a display location 2a in the form of a circle, the property that is associated with the display location 2a such as production lot information and inspection result information can be visually identified in an easy and reliable manner. Therefore, properties can be identified without using a special device or tool.

A marking means can be a conventional one, and for example, felt tipped pen or ink can be used as a marking means as appropriate. Needless to say, this can be used simultaneously with the conventional marking on a location with a defect (in the proximity).

### <Embodiment 11>

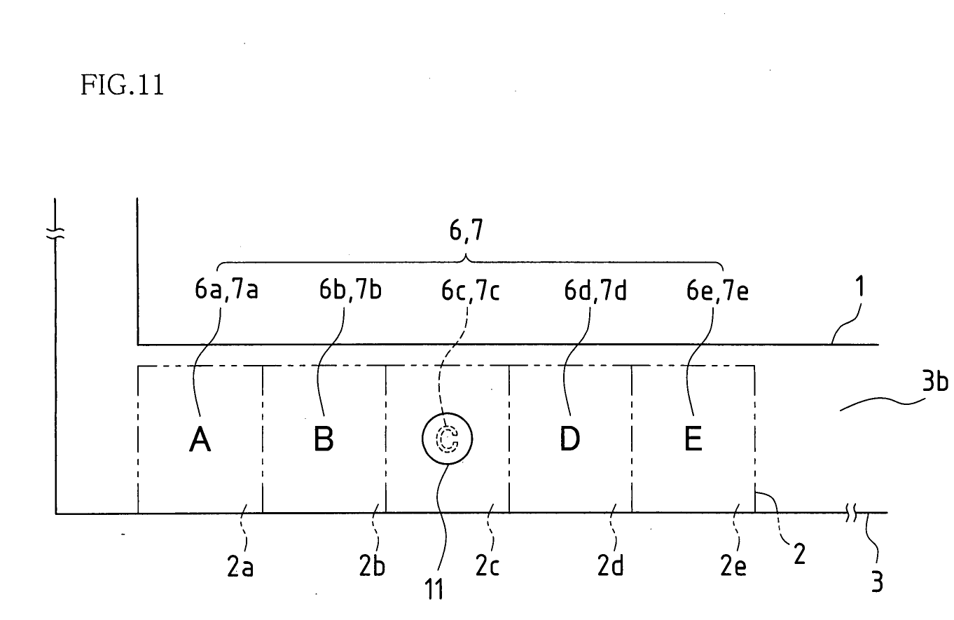

FIG. 11 is a plan view that shows the outline of the relevant portion of the plane surface of a printed wiring substrate for explaining a method for identifying a printed wiring substrate according to Embodiment 11 of the present invention. The same numeric references will be used for the same configuration as the embodiments described above and detailed explanation will be omitted when deemed appropriate.

In this embodiment, instead of the opening portion 10 for identifying the printed wiring substrate 3 that is described in Embodiment 8, a mark 11 is formed as an identifying means in a property display area 2. The property display area 2 has character patterns A, B, C, D, and E formed thereon that serve both as property description display portions 6 (6a, 6b, 6c, 6d, and 6e) and as location display patterns 7 (7a, 7b, 7c, 7d, and 7e) as a means for displaying location.

The mark 11 is formed on a display location 2c by covering (masking) the character pattern C in the shape, for example, of a circle using a marking in ink, felt tipped pen, etc., which can be identified as indicating the property associated with the character pattern C. Although the mark 11 is overlaid on the property description display portions 6cand the location display pattern 7c, it is needless to say that it can also be formed near the property description display portions 6cand the location display pattern 7c.

### <Embodiment 12>

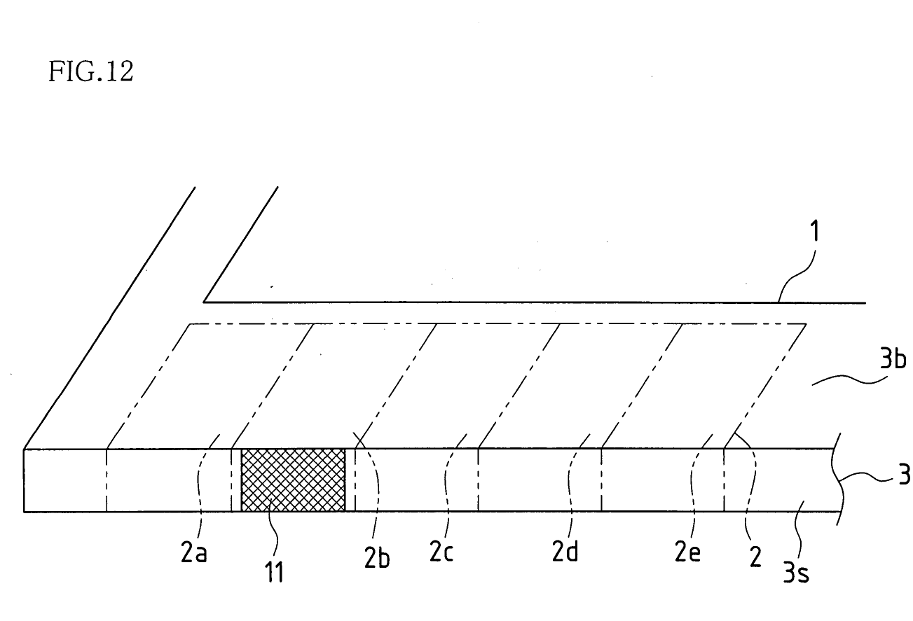

FIG. 12 is a perspective view that shows the outline of the relevant portion of the plane surface and the side edge surface of a printed wiring substrate for explaining a method for identifying a printed wiring substrate according to Embodiment 12 of the present invention. The same numeric references will be used for the same configuration as the embodiments described above and detailed explanation will be omitted when deemed appropriate.

In this embodiment, a mark 11 is formed as an identifying means on a side edge surface 3s of a property display area 2 (waste plate area 3b). It is also possible to form property description display portions 6 and location display patterns 7 on the plane surface area of the property display area 2. Since the side edge surface 3s is used, the planer dimension of the plane surface area of the property display area 2 can be minimized and printed wiring substrates 3 can be identified in a state in which they are stacked with one another.

### <Embodiment 13>

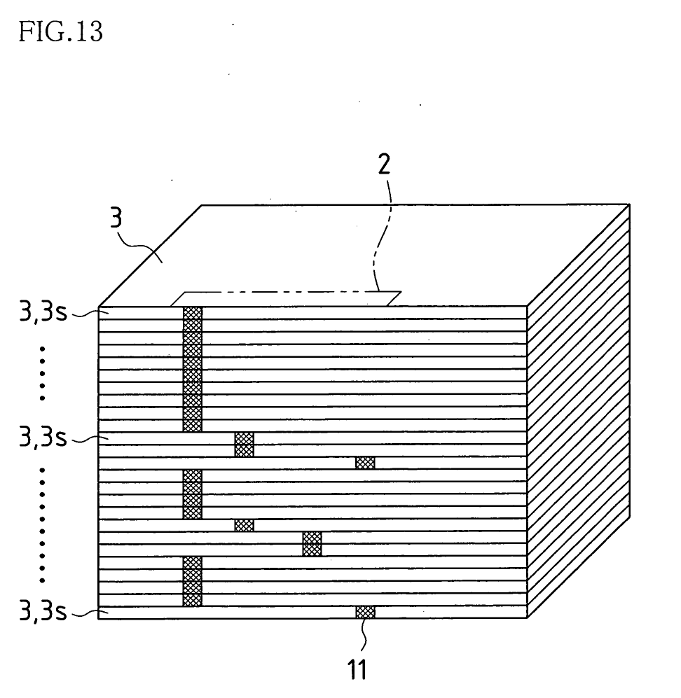

FIG. 13 is a perspective view that shows the outline of the relevant portion of the side edge surface of a state in which a plurality of printed wiring substrates are stacked for explaining a method for identifying a printed wiring substrate according to Embodiment 13 of the present invention. The same numeric references will be used for the same configuration as the embodiments described above and detailed explanation will be omitted when deemed appropriate.

This embodiment is an identifying method when a plurality of the printed wiring substrates 3 described in Embodiment 12 are stacked with one another. The printed wiring substrate 3 is identified in a state in which a plurality of the printed wiring substrate 3 is stacked with one another by visually recognizing the mark 11 formed on the side edge surface 3s. This makes it possible to identify a large number of the printed wiring substrates 3 at a glance, and to easily and reliably prevent mixing in of different printed wiring substrates, mixing of good parts and defectives, etc. when multiple printed wiring substrates of different types having the same outer shape are processed at the same time.

Incidentally, it is needless to say that the same effects can be obtained with the printed wiring substrate 3 that is described in Embodiments 7 and 8, which can be identified with the opening portion 10 (notch) when in a state in which a plurality of the printed wiring substrate 3 are stacked with one another.

### <Embodiment 14>

FIG. 14 is a plan view that shows the outline of the relevant portion of the plane surface of a printed wiring substrate for explaining a method for identifying a printed wiring substrate according to Embodiment 14 of the present invention. The same numeric references will be used for the same configuration as the embodiments described above and detailed explanation will be omitted when deemed appropriate.

In Embodiments 7 to 9, a jig or a device is needed to form the opening portion 10, and in Embodiments 10 to 12, a means for marking is necessary to form the mark 11. On the contrary, this embodiment is a method for identifying the printed wiring substrate 3 according to Embodiment 4, in which an opening portion 10 as an identifying means is formed by removing the lingulate segment 5c. In other words, since the lingulate segment 5c (not shown since the state after the removal is shown) can be easily removed by breaking it off, etc., influences of a jig, a device, or the like on the printed wiring substrate 3 during formation of the opening portion 10 or the mark 11 can be eliminated.

It is needless to say that visibility of the description of a property may also be improved by forming property display portions 6.

### <Embodiment 15>

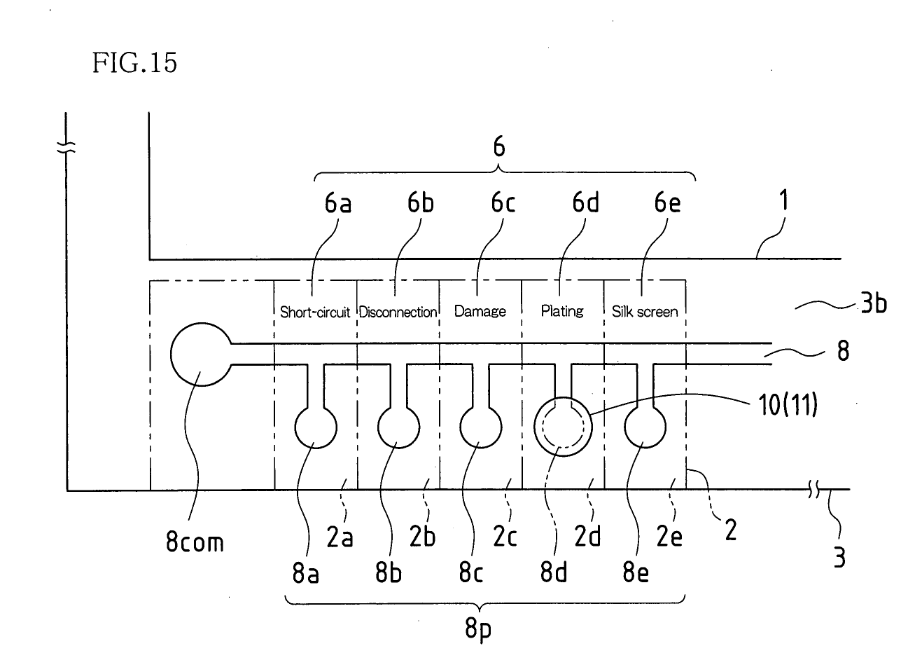

FIG. 15 is a plan view that shows the outline of the relevant portion of the plane surface of a printed wiring substrate for explaining a method for identifying a printed wiring substrate according to Embodiment 15 of the present invention. The same numeric references will be used for the same configuration as the embodiments described above and detailed explanation will be omitted when deemed appropriate.

This embodiment is a method for identifying the printed wiring substrate 3 that is described in Embodiment 6, in which an opening portion 10 as an identifying means is formed by removing the conductor pattern 8 (conductor pad 8p).

More specifically, the opening portion 10 is formed by removing the conductor patterns 8 (conductor pads 8a, 8b, 8c, 8d, and 8e ) that have been formed so as to be associated with the display locations 2a, 2b, 2c, 2d, and 2e. The drawing shows an example in which the conductor pad 8d that is associated with plating defect is removed. The opening portion 10 here is a circular hole and as long as the conductor pad 8d is removed, it does not have to penetrate through.

After removal of the conductor patterns 8, conductivity between the common pad 8com and each of the conductor pads 8a, 8b, 8c, 8d, and 8e are checked using an electrical detecting means (not shown). Since there is no conductivity between the common pad 8com and the conductor pad 8d, the description of the property (plating defect that is associated with the conductor pad 8d) can be electrically identified.

The opening 10 can be replaced with a mark 11. In other words, by forming the mark 11 instead of the opening portion 10 with an insulating ink (application of an insulating material) or the like, electrical identification is possible using an electrical detecting means similarly to when the opening 10 is formed.

Since the printed wiring substrate 3 is identified using an electrical detecting means, an identification result (description of a property) of the printed wiring substrate 3 can be extracted as an electric signal, which makes it possible to easily perform summarization using the signal on a computing device such as computer.

### <Embodiment 16>

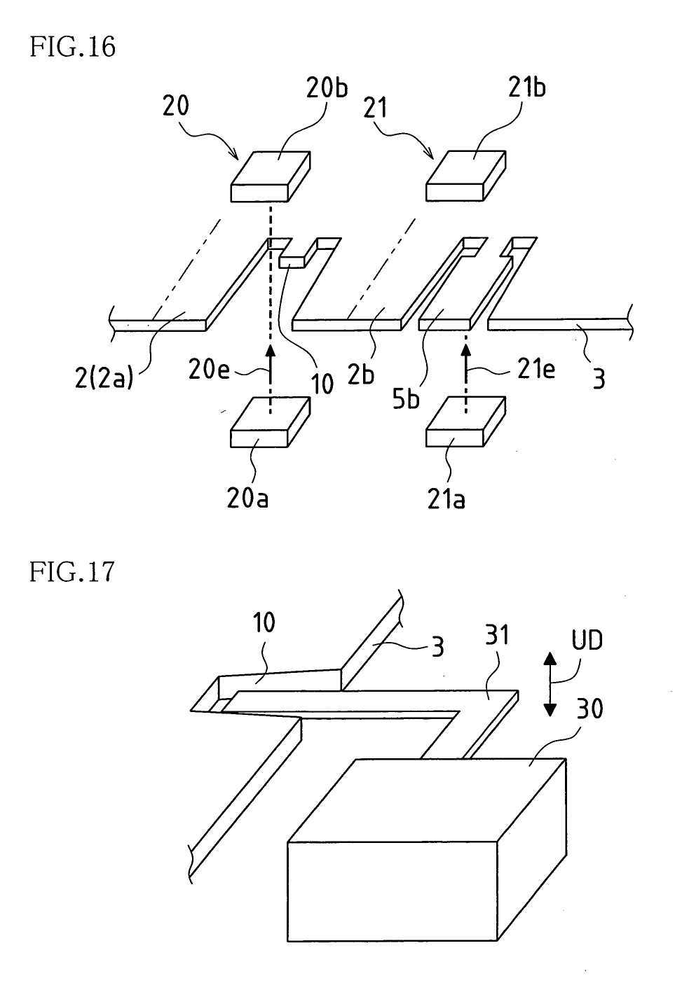

FIG. 16 is a perspective view that explains a method for identifying a printed wiring substrate according to Embodiment 16 of the present invention. The same numeric references will be used for the same configuration as the embodiments described above and detailed explanation will be omitted when deemed appropriate.

This embodiment is a method for identifying a printed wiring substrate 3 using photo interrupters 20 and 21 as an optical detecting means. The photo interrupters 20 and 21 are provided respectively with light emitting portions 20a and 21a and light receptive portions 20b and 21b, and signal lights 20e and 21e are emitted from the light emitting portions 20a and 21a to the light receptive portions 20b and 21b.

A printed wiring board 3 is in a state in which a lingulate segment 5a (see FIGS. 4 and 14) of a property display area 2 (display location 2a) has been removed to form an opening portion 10 based on the inspection result, for example, detection of short-circuit defect, and a lingulate segment 5b is left next to it. Although the printed wiring substrate 3 that is described in Embodiments 4 and 14 is used in this embodiment, needless to say, it is not limited to this. In addition, the photo interrupters 20 and 21 can be used in plurality so that they are associated with lingulate segments 5 or can be used in a configuration in which only one is used so that the lingulate segments 5 are detected sequentially by changing its relative location to the printed wiring substrate 3 (property display area 2).

By placing the printed wiring substrate 3 opposite from the photo interrupters 20 and 21 and emitting the signal lights 20e and 21e from the light emitting portions 20a and 21a to the light receptive portions 20b and 21b, the signal light 20e that corresponds to the opening portion 10 is detected by the light receptive portion 20b and a property of short-circuit defect can be detected. Furthermore, since the signal light 21e is blocked by the lingulate segment 5band not detected by the light receptive portion 21b, the absence of the corresponding disconnection defect can be identified. Accordingly, the identification result (description of a property) of the printed wiring substrate 3 can be detected by the light receptive portions 20b and 21b as an electric signal, which makes it possible to easily perform summarization using the signal on a computing device such as a computer.

In addition, the photo interrupters 20 and 21 can be reflection type although transmission type is indicated herein. For example, the printed wiring substrate 3 can be identified by forming a mark in black ink, etc., and detecting the presence or the absence of the mark by detecting the state of reflection.

### <Embodiment 17>

FIG. 16 is a perspective view that explains a method for identifying a printed wiring substrate according to Embodiment 17 of the present invention. The same numeric references will be used for the same configuration as the embodiments described above and detailed explanation will be omitted when deemed appropriate.

This embodiment is a method for identifying the printed wiring substrate 3 using a microswitch 30 as a mechanical detecting means. The microswitch 30 is provided with a search unit 31 so that, by moving the search unit 31 in an up and down moving direction UD at a location corresponding to an opening portion 10 and detecting on/off state of the microswitch 30, an associated property, for example, short-circuit defect can be detected. The on/off state of the microswitch 30 is converted to an electric signal so that the identification result (description of a property) of the printed wiring substrate 3 can be detected as an electric signal, which makes it possible to easily perform summarization using the signal on a computing device such as computer.

The present invention can be embodied and practiced in other different forms without departing from the spirit and essential characteristics thereof. Therefore, the above-described embodiments are considered in all respects as illustrative and not restrictive. The scope of the invention is indicated by the appended claims rather than by the foregoing description. All variations and modifications falling within the equivalency range of the appended claims are intended to be embraced therein.

1. A printed wiring substrate having a circuit wiring area that has a circuit wiring pattern formed thereon and a peripheral area that is placed in a periphery of the circuit wiring area, wherein:
a property display area that is provided with a display location specified in association with a property for displaying a property of the printed wiring substrate is placed in the peripheral area.

2. A printed wiring substrate having a circuit wiring area that has a circuit wiring pattern formed thereon and a peripheral area that is placed in a periphery of the circuit wiring area, wherein:
a property display area that is provided with a display location specified in association with a property for displaying a property of the printed wiring substrate is placed on a protruding portion formed so as to protrude outside of the peripheral area.

3. The printed wiring substrate according to claim 1, wherein the peripheral area is a waste plate area that is to be cut and discarded prior to incorporation of the printed wiring substrate into a product.

4. The printed wiring substrate according to claim 2, wherein the peripheral area is a waste plate area that is to be cut and discarded prior to incorporation of the printed wiring substrate into a product.

5. The printed wiring substrate according to claim 1, wherein a means for displaying location to indicate the display location is formed in the property display area.

6. The printed wiring substrate according to claim 5, wherein a property description display portion that shows a description of a property associated with the means for displaying location is formed.

7. The printed wiring substrate according to claim 5, wherein the means for displaying location is a lingulate segment.

8. The printed wiring substrate according to claim 6, wherein the means for displaying location is a lingulate segment.

9. The printed wiring substrate according to claim 5, wherein the means for displaying location is a location display pattern.

10. The printed wiring substrate according to claim 6, wherein the means for displaying location is a location display pattern.

11. The printed wiring substrate according to claim 10, wherein the location display pattern simultaneously serves as the property description display portion.

12. The printed wiring substrate according to claim 9, wherein the location display pattern is a conductor pattern formed in the same process as the circuit wiring pattern.

13. The printed wiring substrate according to claim 10, wherein the location display pattern is a conductor pattern formed in the same process as the circuit wiring pattern.

14. The printed wiring substrate according to claim 1, wherein the property is production lot information.

15. The printed wiring substrate according to claim 1, wherein the property is inspection result information.

16. A method for identifying a printed wiring substrate having a circuit wiring area that has a circuit wiring pattern formed thereon and a peripheral area that is placed in a periphery of the circuit wiring area, wherein:
a property display area that is provided with a display location specified in association with a property for displaying a property of the printed wiring substrate is placed in the peripheral area, and
an identifying means is formed in the display location that is associated with a property of the printed wiring substrate.

17. A method for identifying a printed wiring substrate having a circuit wiring area that has a circuit wiring pattern formed thereon and a peripheral area that is placed in a periphery of the circuit wiring area, wherein:
a property display area that is provided with a display location specified in association with a property for displaying a property of the printed wiring substrate is placed on a protruding portion formed so as to protrude outside of the peripheral area, and
an identifying means is formed in the display location that is associated with a property of the printed wiring substrate.

18. The method for identifying a printed wiring substrate according to claim 16, wherein a property description display portion for displaying a description of a property is formed in association with the display location.

19. The method for identifying a printed wiring substrate according to claim 17, wherein a property description display portion for displaying a description of a property is formed so as to be associated with the display location.

20. The method for identifying a printed wiring substrate according to claim 16, wherein the identifying means is an opening portion.

21. The method for identifying a printed wiring substrate according to claim 20, wherein the opening portion is formed by removing a lingulate segment that has been formed in association with the display location.

22. The method for identifying a printed wiring substrate according to claim 20, wherein the opening portion is formed by removing a conductor pattern that has been formed in association with the display location.

23. The method for identifying a printed wiring substrate according to claim 16, wherein the identifying means is a mark.

24. The method for identifying a printed wiring substrate according to claim 18, wherein the identifying means is a mark.

25. The method for identifying a printed wiring substrate according to claim 23, wherein the mark is formed in association with a location display pattern that indicates the display location.

26. The method for identifying a printed wiring substrate according to claim 24, wherein the mark is formed in association with a location display pattern that indicates the display location.

27. The method for identifying a printed wiring substrate according to claim 26, wherein the location display pattern also serves as the property description display portion.

28. The method for identifying a printed wiring substrate according to claim 25, wherein the mark is formed by applying an insulating material to a conductor pattern that has been formed as the location display pattern.

29. The method for identifying a printed wiring substrate according to claim 26, wherein the mark is formed by applying an insulating material to a conductor pattern that has been formed as the location display pattern.

30. The method for identifying a printed wiring substrate according to claim 23, wherein the mark is formed on the side edge surface of the property display area.

31. The method for identifying a printed wiring substrate according to claim 24, wherein the mark is formed on the side edge surface of the property display area.

32. The method for identifying a printed wiring substrate according to claim 16, wherein the property is production lot information.

33. The method for identifying a printed wiring substrate according to claim 16, wherein the property is inspection result information.

34. The method for identifying a printed wiring substrate according to claim 16, wherein the property identified with the identifying means is detected using a detecting means.

35. The method for identifying a printed wiring substrate according to claim 34, wherein the detecting means is either optical, mechanical, or electrical.

36. The method for identifying a printed wiring substrate according to claim 34, wherein the result of detection by the detecting means is summarized.

37. The method for identifying a printed wiring substrate according to claim 17, wherein the protruding portion is removed prior to shipment of the printed wiring substrate.
